(19) United States
(12) Patent Application Publication
(10) Pub. No.: US 2024/0203816 A1
(43) Pub. Date: Jun. 20, 2024

(54) HEAT DISSIPATION STRUCTURES FOR BONDED WAFERS

(71) Applicant: INTERNATIONAL BUSINESS MACHINES CORPORATION, Armonk, NY (US)

(72) Inventors: Kisik Choi, Watervliet, NY (US); Nicholas Alexander POLOMOFF, Hopewell Junction, NY (US); Brent A. Anderson, Jericho, VT (US); Lawrence A. Clevenger, Saratoga Springs, NY (US); Ruilong Xie, Niskayuna, NY (US); Terence Hook, Jericho Center, VT (US); Matthew Angyal, Stormville, NY (US); FEE LI LIE, Albany, NY (US)

(21) Appl. No.: 18/067,207

(22) Filed: Dec. 16, 2022

(51) Int. Cl. H01L 23/367; H01L 23/00; H01L 23/522; H01L 23/528

(52) U.S. Cl. CPC H01L 23/367; H01L 23/5226; H01L 23/528; H01L 24/05; H01L 24/08; H01L 24/80; H01L 23/3735; H01L 2224/05647; H01L 2224/08225; H01L 2224/80006; H01L 2224/80357; H01L 2224/80379; H01L 2224/80447; H01L 2924/0504; H01L 2924/0544

(57) ABSTRACT

Semiconductor devices and methods of forming the same include a front-end-of-line (FEOL) layer. A back-end-of-line (BEOL) layer includes a thermal transfer structure in contact with the FEOL layer. A carrier wafer is bonded to the BEOL layer and includes a thermal dissipation structure in contact with the thermal transfer structure.

### BACKGROUND

The present invention generally relates to semiconductor device fabrication and, more particularly, to fabrication of devices that include backside power distribution.

Some semiconductor devices use a semiconductor substrate as a heat sink that helps dissipate heat from front-end-of-line (FEOL) devices. Such devices, such as transistors and other active devices, generate heat during operation. If the heat is not effectively dissipated, then malfunctions and damage can result.

### SUMMARY

A semiconductor device includes a front-end-of-line (FEOL) layer. A back-end-of-line (BEOL) layer includes a thermal transfer structure in thermal contact with the FEOL layer. A carrier wafer is bonded to the BEOL layer and includes a thermal dissipation structure in thermal contact with the thermal transfer structure.

A semiconductor device includes a FEOL layer that includes a thermal via. A BEOL layer includes a first thermal transfer structure in thermal contact with the thermal via. A backside layer, on a side of the FEOL opposite to the BEOL layer, includes a second thermal transfer structure in thermal contact with the thermal via. A carrier wafer is bonded to the BEOL layer and includes a thermal dissipation structure in thermal contact with the first thermal transfer structure.

A method of forming a semiconductor device includes forming a FEOL layer. A BEOL is formed on the FEOL layer and includes a first thermal transfer structure. A first bonding layer is formed on the BEOL layer and includes a thermal via in thermal contact with the first thermal transfer structure. A carrier wafer is bonded to the BEOL layer using the first bonding layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of a semiconductor device with backside layers and with thermal dissipation structures through frontside layers to a heat sink wafer, showing the formation of a front-end-of-line (FEOL) layer having thermal vias in accordance with an embodiment of the present invention;

FIG. 2 is a cross-sectional view of a step in the fabrication of a semiconductor device with backside layers and with thermal dissipation structures through frontside layers to a heat sink wafer, showing the formation of a frontside back-end-of-line (BEOL) layer having a variety of thermal dissipation structures in accordance with an embodiment of the present invention;

FIG. 3 is a cross-sectional view of a step in the fabrication of a semiconductor device with backside layers and with thermal dissipation structures through frontside layers to a heat sink wafer, showing the formation of bonding layer thermal vias in accordance with an embodiment of the present invention;

FIG. 4 is a cross-sectional view of a step in the fabrication of a semiconductor device with backside layers and with thermal dissipation structures through frontside layers to a heat sink wafer, showing the bonding of a carrier wafer to the bonding layer to act as mechanical support and a heat sink in accordance with an embodiment of the present invention;

FIG. 5 is a cross-sectional view of a step in the fabrication of a semiconductor device with backside layers and with thermal dissipation structures through frontside layers to a heat sink wafer, showing the removal of a backside substrate in accordance with an embodiment of the present invention;

FIG. 6 is a cross-sectional view of a step in the fabrication of a semiconductor device with backside layers and with thermal dissipation structures through frontside layers to a heat sink wafer, showing the formation of backside layers that include a variety of thermal dissipation structures in accordance with an embodiment of the present invention;

FIG. 7 is a cross-sectional view of a step in the fabrication of an alternative embodiment of a semiconductor device with backside layers and with thermal dissipation structures through frontside layers to a heat sink wafer, where the carrier wafer includes heat dissipation lines in accordance with an embodiment of the present invention;

FIG. 8 is a cross-sectional view of a step in the fabrication of an alternative embodiment of a semiconductor device with backside layers and with thermal dissipation structures through frontside layers to a heat sink wafer, where the carrier wafer includes heat dissipation pads in accordance with an embodiment of the present invention;

FIG. 9 is a cross-sectional view of a step in the fabrication of an alternative embodiment of a semiconductor device with backside layers and with thermal dissipation structures through frontside layers to a heat sink wafer, where the carrier wafer includes heat dissipation pads and where the frontside BEOL layer includes heat dissipation pads in accordance with an embodiment of the present invention;

FIG. 10 is a cross-sectional view of a step in the fabrication of an alternative embodiment of a semiconductor device with backside layers and with thermal dissipation structures through frontside layers to a heat sink wafer, where the carrier wafer includes heat dissipation lines and where the frontside BEOL layer includes heat dissipation pads in accordance with an embodiment of the present invention;

FIG. 11 is a cross-sectional view of a step in the fabrication of an alternative embodiment of a semiconductor device with backside layers and with thermal dissipation structures through frontside layers to a heat sink wafer, where the carrier wafer includes heat dissipation lines and the frontside BEOL layer includes heat dissipation lines in accordance with an embodiment of the present invention; and

FIG. 12 is a block/flow diagram of a method of fabricating a semiconductor device with backside layers and with thermal dissipation structures through the frontside layers to a heat sink wafer, in accordance with an embodiment of the present invention.

### DETAILED DESCRIPTION

In semiconductor devices that include backside power distribution networks, the front-end-of-line (FEOL) devices may have difficulty dissipating waste heat. This is because, instead of having a semiconductor substrate with a relatively high thermal conductivity to use as a heat sink, such as a silicon substrate, the FEOL layer may be bonded to one or more backside interconnect layers. These backside interconnect layers may be formed from dielectric materials with relatively low thermal conductivity, such that heat transfer into those layers is much slower relative to heat transfer into silicon. A semiconductor wafer may still be used to provide structural support to the device, but such a wafer may be bonded to the device using a bonding dielectric material, which may also have a relatively low thermal conductivity and may therefore inhibit transfer of heat into the wafer. As a result, the heat that is generated by the FEOL devices may be trapped within the FEOL layer, causing overheating, malfunctions, and potentially damage.

To address this, thermal transfer structures may be formed within the back-end-of-line (BEOL) layers and backside power distribution layers. The bonding dielectrics that are used to bond the device to a semiconductor handler wafer may similarly be formed with thermal transfer structures. A result is that thermal pathways are created through the low-conductivity dielectric materials and to the semiconductor handler wafer, so that heat that is generated from the FEOL layer can travel out to the handler wafer for safe dissipation. These thermal transfer structures may include purpose-built structures, and may furthermore include structures that serve other functions within the device, such as crack stop structures.

For example, whereas copper has a thermal conductivity of 390 W/mK, a dielectric material such as silicon dioxide has a thermal conductivity of only 1.2 W/mK. As the thickness of the silicon dioxide grows, the thermal conductivity decreases proportionally. However, even a modestly sized metal via that penetrates the dielectric layer can dramatically increase the thermal conductivity as compared to the use of silicon dioxide alone, and can approach the thermal conductivity of a solid copper layer. While the use of copper for thermal transfer structures is specifically contemplated, particularly in examples where the BEOL layers use copper interconnects for power and signal communication, any appropriate metal, such as tungsten, ruthenium, or cobalt can be used instead and may be selected to match the metal used for interconnects elsewhere in the device.

There are multiple types of thermal transfer structures that may be employed for this purpose. For example, crack stop structures can be used to serve a dual purpose of adding mechanical resiliency as well as providing thermal structure. Purpose-built structures, such as the spire and pagoda structures described below, can also be added specifically to active device regions in the chip. Such structures can be added in both the frontside processes (e.g., formation of BEOL layers) and the backside processes (e.g., formation of backside power distribution layers). These thermal transfer structures may then interface with thermal vias in the bonding oxide to transfer waste heat to the semiconductor handler wafer.

Referring now to FIG. 1, a cross-sectional view of a step in the fabrication of a semiconductor device is shown. A substrate includes a carrier substrate 102, an etch stop layer 104, and a device substrate 106. An FEOL layer 108 is formed on, or from, the device substrate 106 and may include one or more FEOL devices (not shown), for example including active devices such as transistors and/or passive devices such as capacitors, inductors, resistors, and transmission lines.

The FEOL layer 108 includes vias 110. These vias 110 may be used to communicate with a backside power rail, for example providing power to the FEOL devices. During operation, the FEOL devices generate heat within the FEOL layer 108. The vias 110 may act as thermal transfer structures, transferring heat from the FEOL devices to other thermal transfer structures on layers above and/or below the FEOL layer 108. The vias 110 may be formed from a material which provides both electrical and thermal conductivity, such as copper or another metal.

The carrier substrate 102 and the device substrate 106 may be formed from a silicon-containing material. Illustrative examples of silicon-containing materials suitable for these substrates include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although the carrier substrate 102 and the device substrate 106 are shown and described herein as being formed from the same material, these structures may also be formed from different materials. In some cases, the carrier substrate may not be formed from a semiconductor material at all.

The etch stop layer 104 is formed from a material that has etch selectivity with respect to the material of the carrier substrate 102 and the device substrate 106. For example, silicon dioxide or silicon germanium may be used to form the etch stop layer 104. As used herein, the term “selective” in reference to a material removal process denotes that the rate of material removal for a first material is greater than the rate of removal for at least another material of the structure to which the material removal process is being applied.

The vias 110 may be formed from any appropriate electrically conductive material, such as, e.g., tungsten, nickel, titanium, molybdenum, tantalum, copper, platinum, silver, gold, ruthenium, iridium, rhenium, rhodium, cobalt, and alloys thereof. Electrically conductive materials tend to have good thermal conductivity as well, but the material of the vias 110 may be selected to provide high electrical conductivity and thermal conductivity. For example, copper with a high degree of purity may be used for the vias 110.

Referring now to FIG. 2, a cross-sectional view of a step in the fabrication of a semiconductor device is shown. BEOL layers 202 may be formed on the FEOL layer 108, with connections being made to the FEOL devices via any appropriate middle-of-line contacts that may be needed.

The vias 110 may connect to a variety of thermal transfer structures in the BEOL layers 202. For example, crack stop structures 204 may be formed in the BEOL layers 202 from any appropriate thermally conductive material, such as copper. The crack stop structures 204 may include vertical vias and horizontal connecting structures that pass through a dielectric material of the BEOL layers 202, so that if a crack or fissure develops in the BEOL layers 202, it may be stopped from propagating further than the crack stop structures 204. The crack stop structures 204 may further fill the role of providing thermal conduction of heat away from the FEOL layer 108, and so may make thermal contact with the vias 110.

Additional thermal transfer structures 206 may be included, such as a spire structure that has vertical vias and horizontal connecting structures. The thermal transfer structures 206 may be formed from any appropriate thermally conductive material, such as copper. The thermal transfer structures 206 may penetrate the BEOL layers 202, but need not have crack stop properties and may occupy smaller areas of the wafer. In some examples, the crack stop structures 204 may be formed in peripheral areas of the wafer, while the thermal transfer structures 206 may be positioned closer to devices in the FEOL layer 108.

Although spire structures are shown herein, where the horizontal connecting structures take up roughly the same horizontal area as a perimeter defined by the vertical vias, pagoda structures are also contemplated. In a pagoda structure, the horizontal connecting structures may exceed the lateral bounds of the perimeter defined by the vertical vias for a given thermal transfer structure. In such an embodiment, the horizontal parts of the thermal transfer structures 206 may extend laterally past the vertical vias of their respective thermal transfer structures 206. In some embodiments, a given thermal transfer structure may have parts that are spire-like and parts that are pagoda-like. In some embodiments, some thermal transfer structures 206 may have a spire configuration, while other thermal transfer structures 206 may have a pagoda configuration.

Also shown are interconnects 208, which may provide power and signal communications to devices to devices in the FEOL layer 108, and which are shown herein as having a pagoda structure. The interconnects 208 may include horizontal conductive interconnect structures that transmit power and signals from one part of the wafer to another and to off-chip devices, as well as vertical conductive vias that transmit power and signals between BEOL layers 202 and to the FEOL layer 108. The interconnects 208 may be formed from an electrically conductive and thermally conductive material, such as copper, so that they also serve to move heat away from the devices of the FEOL layer 108.

These structures may be formed within the BEOL layers 202 as the BEOL layers 202 are progressively formed. For example, a layer of dielectric material may be deposited by any appropriate deposition process. In some embodiments, silicon dioxide may be deposited to a predetermined thickness on the FEOL layer 108. The layer of dielectric material may then be patterned to form vias and trenches. The vias may penetrate the layer of dielectric material, exposing he underlying layer, while the trenches may be shallower to preserve electrical insulation with the underlying layer. The vias and trenches may then be filled by a deposition of any appropriate conductive material to form parts of the crack stop structures 204, the thermal transfer structures 206, and the interconnects 208. Each successive layer may then deposit additional dielectric material over the previous layer, with new vias and trenches, and may similarly be filled with conductive material, until the BEOL layers 202 are complete.

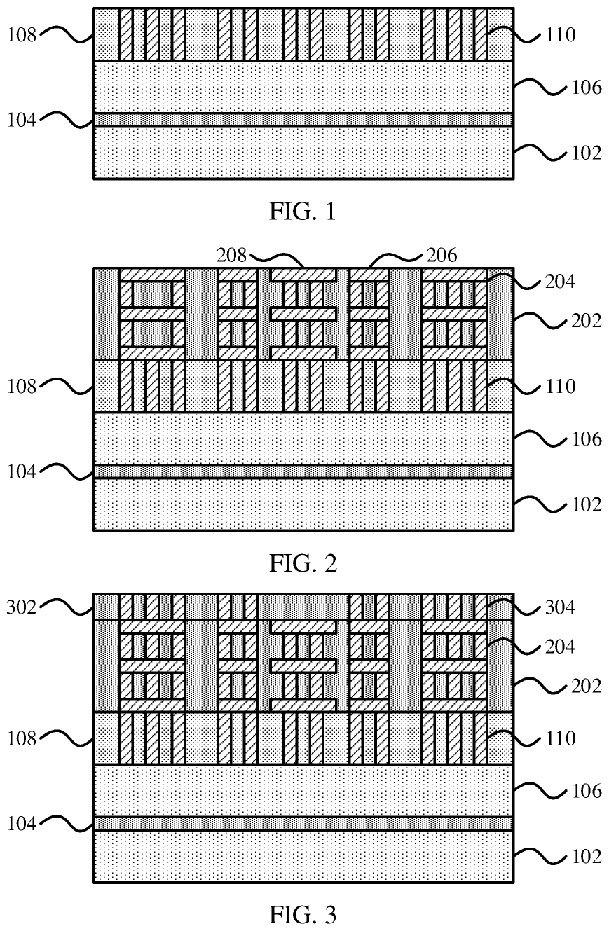

Referring now to FIG. 3, a cross-sectional view of a step in the fabrication of a semiconductor device is shown. A bonding layer 302 is formed on the BEOL layers 202, for example by depositing any appropriate bonding dielectric material, such as silicon oxide or silicon nitride. The bonding layer 302 is then patterned to form vias that penetrate to the underlying BEOL layers 202. Thermally conductive material, such as copper, is then deposited in the vias using any appropriate deposition process to make thermal vias 304 that penetrate the bonding layer 302 and that make thermal contact with the crack stop structures 204 and/or the thermal transfer structures 206. No thermal vias 304 are formed in contact with the interconnects 208, to prevent the interconnects 208 from electrically shorting to the handler wafer. The top of the bonding layer 302 may be planarized to polish away any excess material from the thermal vias 304, for example using a chemical mechanical planarization (CMP) process.

As used herein, the term “thermal contact” refers to contact between two structures that can conduct heat efficiently. In some examples, thermal contact may be satisfied by direct contact between the two structures. However, thermal contact between a first structure and a second structure may also include intervening structures if those intervening structures themselves have a sufficiently high thermal conductivity. In some embodiments, thermal contact may be satisfied by intervening structures that have a thermal conductivity greater than that of silicon dioxide. In some embodiments, thermal contact may be satisfied by intervening structures that have a thermal conductivity on the order of a metal material. In some embodiments, thermal contact may be satisfied by intervening structures that have a thermal conductivity on the order of copper.

CMP is performed using, e.g., a chemical or granular slurry and mechanical force to gradually remove upper layers of the device. The slurry may be formulated to be unable to dissolve, for example, the bonding layer 302, resulting in the CMP process's inability to proceed any farther than that layer.

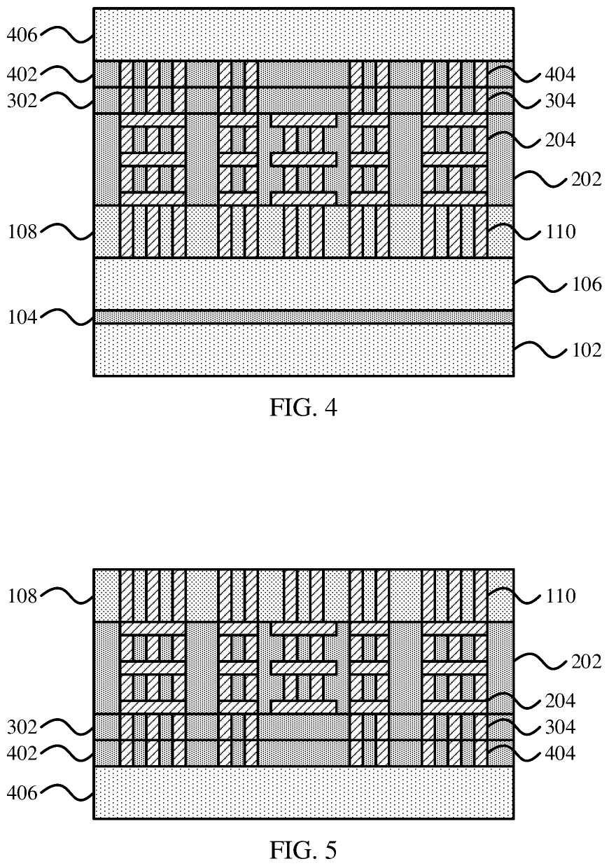

Referring now to FIG. 4, a cross-sectional view of a step in the fabrication of a semiconductor device is shown. A handler wafer 406 is bonded to the device wafer using a handler bonding layer 402. The handler wafer 406 may be formed from silicon or any other material having appropriate levels of mechanical stiffness and thermal conductivity, while the handler bonding layer 402 may be formed from any appropriate bonding dielectric material, such as silicon dioxide or silicon nitride.

The handler bonding layer 402 may be formed with thermal vias 404, for example by patterning the handler bonding layer 402, depositing a thermally conductive material such as copper, and then polishing down to the dielectric material of the handler bonding layer 402 to remove excess thermally conductive material. The handler wafer 406 may then be positioned over the bonding layer 302, with the thermal vias 404 of the handler bonding layer 402 aligning with the thermal vias 304 of the bonding layer 302. The two bonding layers may then be bonded together, so that the handler wafer 406 can be used to manipulate the set. Bonding the handler wafer 406 causes the thermal vias 404 of the handler bonding layer 402 to make thermal contact with the thermal vias 304 of the bonding layer 302.

Referring now to FIG. 5, a cross-sectional view of a step in the fabrication of a semiconductor device is shown. Using the handler wafer 406, the entire stack may be flipped upside down, exposing the carrier substrate 102. The carrier substrate 102, etch stop layer 104, and device substrate 106 may then be removed in successive etch steps, exposing the underside of the FEOL layer 108 and the vias 110 therein. In some cases, parts of the device substrate 106 may remain within the FEOL layer 108 as part of one or more FEOL devices.

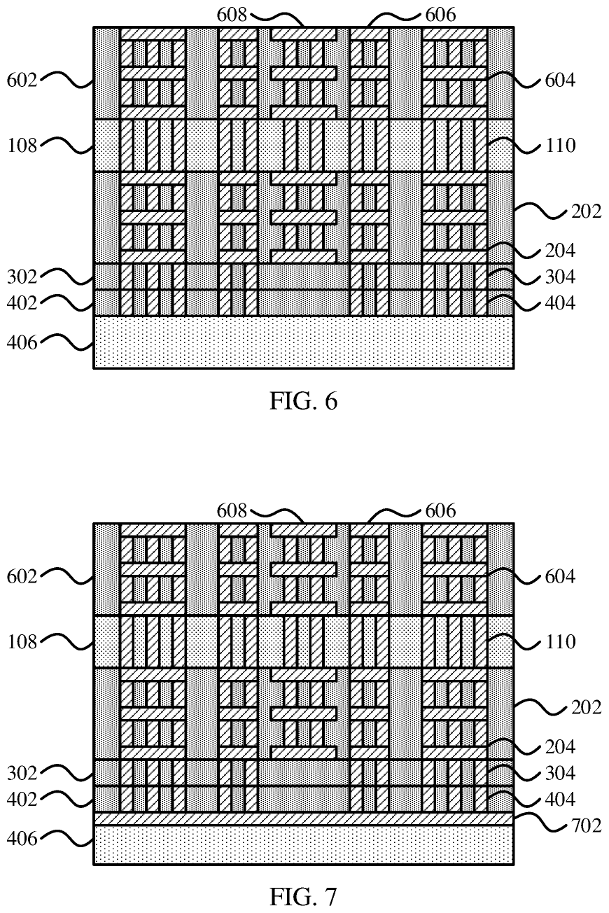

Referring now to FIG. 6, a cross-sectional view of a step in the fabrication of a semiconductor device is shown. Backside layers 602 are formed on the FEOL layer 108, making thermal contact with vias 110. Like the BEOL layers 202, the backside layers 602 may have various structures embedded in them, including crack stop structures 604, thermal transfer structures 606, and interconnects 608. The interconnects 608 may form, for example, a backside power distribution network that distributes power to devices in the FEOL layer 202. Additional layers may be formed on the backside layers 602, for example including relatively thick wire layers and interconnects that may be used to connect the wafer to other devices. The thermal transfer structures 606 may be placed to prevent electrical shorts to interconnects in the BEOL layers 202.

The thermal transfer structures 606 of the backside layers 602 may connect to the thermal transfer structures 206 of the BEOL layers 202 by way of the vias 110 in the FEOL layer 108, making thermal contact between the backside layers 602 and the BEOL layers 202. However, other embodiments may include thermal transfer structures that do not run through the entire thickness of the chip. In addition, lateral thermally conductive structures may help to better distribute heat through the chip. While thermal structures on the backside layers 602 may not dissipate as much heat as those of the BEOL layers 202, as they do not connect to a heat sink, they may provide additional mechanical stability needed for packaging.

Referring now to FIG. 7, a cross-sectional view of a semiconductor device is shown. In some embodiments, heat-dissipating wiring 702 may be formed in the handler wafer 406 before it is bonded to the BEOL layers 202. The heat-dissipating wiring 702 may be formed by, for example, etching trenches in the surface of the handler wafer 406 before the handler bonding layer 402 is applied. The trenches may be filled with a thermally conductive material, such as copper, using any appropriate deposition process. The thermally conductive material may then be polished down to the level of the surface of the handler wafer 406, thereby separating the thermally conductive material into wires. The heat-dissipating wiring 702 can help to better distribute heat across the heat sink formed by the carrier wafer 406.

Referring now to FIG. 8, a cross-sectional view of a semiconductor device is shown. In some embodiments, heat dissipating pads 802 may be formed in the handler wafer 406 before it is bonded to the BEOL layers 202. The heat dissipating pads 802 may be formed by, for example, patterning the surface of the handler wafer 406 before the handler bonding layer 402 is applied to create depressions. The depressions may be filled with a thermally conductive material, such as copper, using any appropriate deposition process. The thermally conductive material may then be polished down to the level of the surface of the handler wafer 406, thereby separating the thermally conductive material into pads. The use of heat dissipating pads 802 increases the thermal contact area between the vias 404 and the carrier wafer 406.

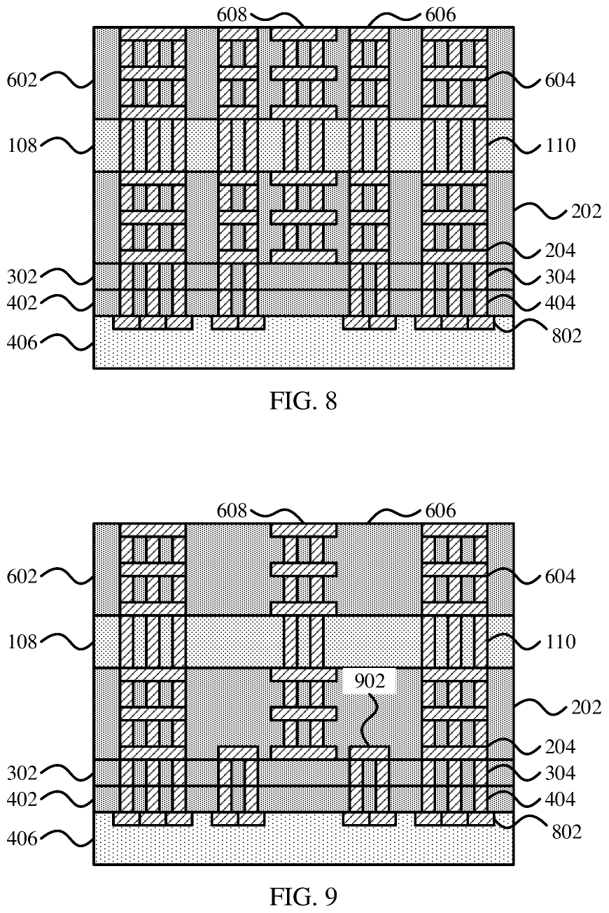

Referring now to FIG. 9, a cross-sectional view of a semiconductor device is shown. In some embodiments, the heat transfer structures may not penetrate through the BEOL layers 202 and the backside layers 602, but may instead be pads 902 that are formed at the interface between the BEOL layers 202 and the bonding layer 302. These pads 902 function to pull heat from the BEOL layers 202, where heat would otherwise be generated and accumulate, so that it can be transferred to the carrier wafer 406. The crack stop structures 204, which perform a structural/mechanical function as well, may be maintained to further provide thermal transfer to the carrier wafer 406.

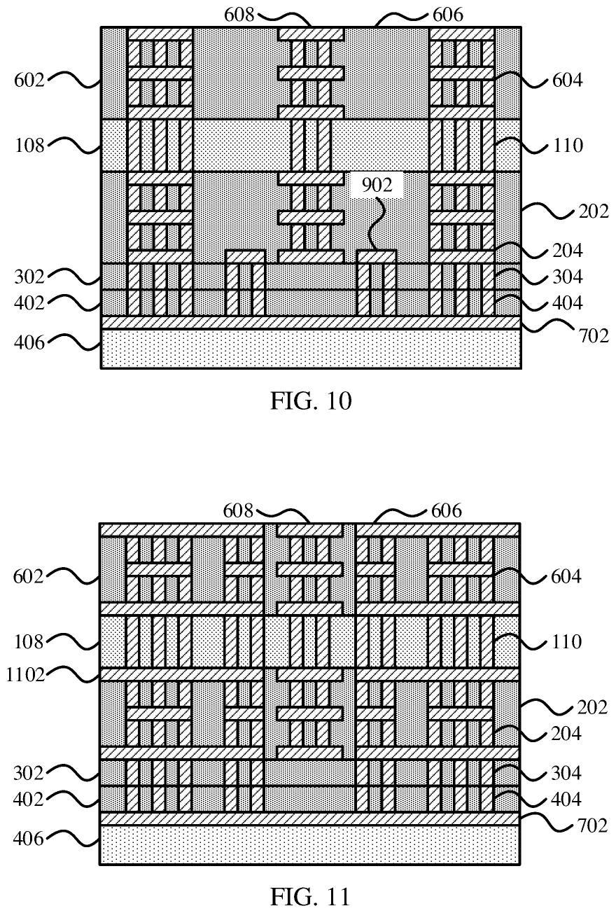

Referring now to FIG. 10, a cross-sectional view of a semiconductor device is shown. As in FIG. 9 above, the thermal transfer structures may be designed as pads 902 at the interface between the BEOL layers 202 and the bonding layer 302. Instead of pads in the carrier wafer 406, the heat-dissipating wiring 702 may be used.

Referring now to FIG. 11, a cross-sectional view of a semiconductor device is shown. In some embodiments, horizontal wiring 1102 may be added, for example between thermal transfer structures 206/606 and crack stop structures 204/604. The horizontal wiring 1102 may act as a net to catch heat that is generated and that accumulates within the BEOL layers 202 and backside layers 602. In some embodiments, the horizontal wiring 1102 may further be connected to wiring on other levels of the BEOL layers 202 or the backside layers 602, for example using conductive vias.

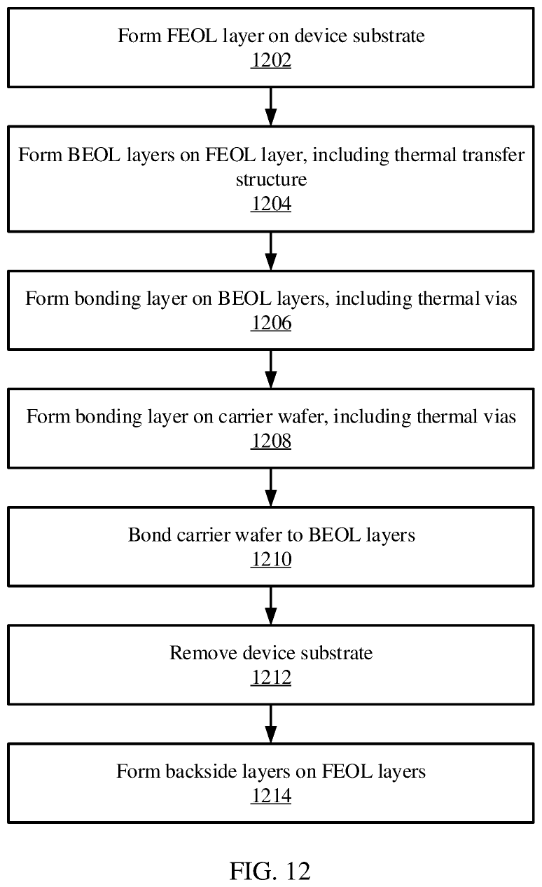

Referring now to FIG. 12, a method of forming a semiconductor device is shown. Block 1202 forms FEOL layer 108 on a device substrate 106. The FEOL layer 108 is formed to include any appropriate devices, for example including active circuit devices like transistors and passive circuit devices like capacitors, inductors, and resistors. The FEOL layer 108 further includes thermal vias 110 that penetrate the FEOL layer 108 and that are filled with a thermally conductive material. Block 1202 may form the thermal vias 110 by etching holes through the FEOL layer 108, depositing a thermally conductive material using any appropriate deposition process, and then polishing the thermally conductive material off of the surface of the FEOL layer 108.

Block 1204 forms BEOL layers 202 on the FEOL layer 108. The BEOL layers 202 may include one or more layers of dielectric material with any appropriate structures formed therein. For example, the BEOL layers 202 may include crack stop structures 204, thermal transfer structures 206, and interconnects. Structures within the BEOL layers 202 may be formed by patterning the dielectric material of the BEOL layers 202 to include trenches and vias, followed by the deposition of an appropriate thermally conductive material, such as copper. The structures within the BEOL layers 202 may be positioned to align with the thermal vias 110 of the FEOL layer 108 to provide a thermal pathway between the layers.

Block 1206 forms a bonding layer 302 on the BEOL layers 202. The bonding layer 302 may be formed from, e.g., silicon oxide or silicon nitride and may include thermal vias 304 that align with the thermal structures of the BEOL layers 202. Thermal vias 304 may be omitted in the areas over the interconnects 208 within the BEOL layers 202 to prevent the interconnects 208 from shorting to the carrier wafer.

Block 1208 forms a bonding layer 402 on a carrier wafer 406. The bonding layer 402 may be formed from, e.g., silicon oxide or silicon nitride and may include thermal vias 404. The bonding layer 402 may further be prepared to include heat dissipating wires 702 or pads 802 that align with the thermal vias 404. Block 1210 bonds the carrier wafer 406 to the BEOL layers 202 using the bonding layers 302 and 402. The thermal vias 404 and 304 may be aligned to one another to provide a thermal conduction pathway from the BEOL layers 202 to the carrier wafer 406.

Block 1212 removes the device substrate 106, for example using an etching or polishing process. Block 1214 then forms backside layers 602 on the exposed backside surface of the FEOL layer 108. Block 1214 may form the backside layers 602 to include crack stop structures 604, thermal transfer structures 606, and/or interconnects 608, each of which may align with thermally conductive vias 110 of the FEOL layer. Additional structures may be formed on the backside layers 602 to provide connections to off-chip structures.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of heat dissipation structures for bonded wafers (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a front-end-of-line (FEOL) layer;
a back-end-of-line (BEOL) layer that includes a thermal transfer structure in contact with the FEOL layer; and
a carrier wafer bonded to the BEOL layer that includes a thermal dissipation structure in thermal contact with the thermal transfer structure.

2. The semiconductor device of claim 1, wherein the thermal transfer structure includes vertical vias relative to a plane of the FEOL layer and penetrates the BEOL layer to make thermal contact with the FEOL layer.

3. The semiconductor device of claim 2, wherein the FEOL layer includes a first thermal via that makes thermal contact with the thermal transfer structure.

4. The semiconductor device of claim 3, further comprising a backside layer, on a side of the FEOL layer opposite to the BEOL layer, wherein the backside layer includes a thermal transfer structure that completely penetrates the backside layer and that is in thermal contact with the thermal via.

5. The semiconductor device of claim 3, wherein the BEOL layer further includes a crack stop structure formed from a thermally conductive material that makes thermal contact with a second thermal via of the FEOL layer.

6. The semiconductor device of claim 1, further comprising a bonding layer between the BEOL layer and the carrier wafer that includes a thermal via between the thermal transfer structure and the thermal dissipation structure to make thermal contact with the thermal transfer structure and the thermal dissipation structure.

7. The semiconductor device of claim 1, wherein the thermal transfer structure includes a pad of thermally conductive material on a surface of the BEOL layer.

8. The semiconductor device of claim 1, wherein the heat dissipating structure includes a wire that connects to multiple thermal transfer structures.

9. The semiconductor device of claim 1, wherein the BEOL layer further includes a horizontal thermally conductive wire that thermally connects multiple thermal transfer structures together.

10. A semiconductor device, comprising:
a front-end-of-line (FEOL) layer that includes a thermal via;
a back-end-of-line (BEOL) layer that includes a first thermal transfer structure in thermal contact with the thermal via;
a backside layer, on a side of the FEOL opposite to the BEOL layer, that includes a second thermal transfer structure in thermal contact with the thermal via; and
a carrier wafer bonded to the BEOL layer that includes a thermal dissipation structure thermal in contact with the first thermal transfer structure.

11. The semiconductor device of claim 10, wherein the BEOL layer further includes a crack stop structure formed from a thermally conductive material that makes thermal contact with a second thermal via of the FEOL layer.

12. The semiconductor device of claim 10, further comprising a bonding layer between the BEOL layer and the carrier wafer that includes a thermal via between the first thermal transfer structure and the thermal dissipation structure to make thermal contact with the thermal transfer structure and the thermal dissipation structure.

13. The semiconductor device of claim 10, wherein the heat dissipating structure includes a wire that connects to multiple thermal transfer structures.

14. The semiconductor device of claim 10, wherein the BEOL layer further includes a horizontal thermally conductive wire that thermally connects multiple thermal transfer structures together.

15. A method of forming a semiconductor device, comprising:
forming a front-end-of-line (FEOL) layer;
forming a back-end-of-line (BEOL) layer on the FEOL layer that includes a first thermal transfer structure;
forming a first bonding layer on the BEOL layer that includes a thermal via in thermal contact with the first thermal transfer structure; and
bonding a carrier wafer to the BEOL layer using the first bonding layer.

16. The method of claim 15, further comprising forming a second bonding layer on the carrier wafer that includes a thermal via in thermal contact with the carrier wafer before bonding the carrier wafer to the BEOL layer.

17. The method of claim 15, forming a heat dissipating structure on the carrier wafer before forming the second bonding layer, wherein the thermal via of the second bonding layer aligns with the heat dissipating structure.

18. The method of claim 17, wherein forming the heat dissipating structure includes forming a thermally conductive line on a surface of the carrier wafer that has a length such that the thermally conductive line contacts multiple thermal transfer structures when the carrier wafer is bonded to the BEOL layer.

19. The method of claim 15, wherein forming the FEOL layer includes forming a thermal via and forming the BEOL layer includes forming the first thermal transfer structure in thermal contact with the thermal via.

20. The method of claim 19, further comprising forming a backside layer on a side of the FEOL layer opposite to the BEOL layer, including forming a second thermal transfer structure in the backside layer in thermal contact with the thermal via.
